(19) United States
(12) Patent Application Publication
(10) Pub. No.: US 2018/0190761 A1
(43) Pub. Date: Jul. 5, 2018

(54) MIM CAPACITOR WITH ENHANCED CAPACITANCE

(71) Applicant: Micron Technology, Inc., Boise, ID (US)

(72) Inventors: Hsu Chiang, New Taipei City (TW); Neng-Tai Shih, New Taipei City (TW); Tieh-Chiang Wu, Taoyuan City (TW)

(21) Appl. No.: 15/396,828

(22) Filed: Jan. 3, 2017

(51) Int. Cl. H01L 49/02; H01L 23/528; H01L 23/522; H01L 23/532; H01L 21/288; H01L 21/027

(52) U.S. Cl. CPC H01L 28/90; H01L 23/528; H01L 23/5223; H01L 21/0273; H01L 23/53238; H01L 21/288; H01L 23/5226

(57) ABSTRACT

A metal-insulator-metal (MIM) capacitor is disclosed. The MIM capacitor includes a substrate having a first dielectric layer thereon and a bottom electrode embedded in the first dielectric layer. The bottom electrode includes a metal plate and a three-dimensional (3D) metal structure protruding from a top surface of the metal plate. A second dielectric layer surrounds the 3D metal structure. A capacitor dielectric layer covers the 3D metal structure and the second dielectric layer. A top electrode is disposed on the capacitor dielectric layer. The top electrode has fins that interdigitate with the 3D metal structure.

### TECHNICAL FIELD

The present application relates to semiconductor technology and, more particularly, to a semiconductor structure containing a metal-insulator-metal (MIM) capacitor structure that has enhanced capacitance, and a method of forming the same.

### BACKGROUND

On-chip MIM capacitors are known in the art. The on-chip MIM capacitors are typically integrated with mixed signal circuits or radio frequency (RF) circuits and may serve as decoupling capacitors to provide improved voltage regulation and noise immunity for power distribution.

To ensure a minimal capacitance, a large chip area is usually used for the on-chip MIM capacitor which, in turn, adversely increases the chip size and thus the cost of the chip. Thus, there is a need for providing on-chip MIM capacitors that have enhanced capacitance without increasing the size of the chip or the cost of the chip.

### BRIEF SUMMARY

It is one object of the invention to provide a three-dimensional (3D) MIM capacitor with increased capacitance.

According to one aspect of the disclosure, a metal-insulator-metal (MIM) capacitor is disclosed. The MIM capacitor includes a substrate having a first dielectric layer thereon and a bottom electrode embedded in the first dielectric layer. The bottom electrode includes a metal plate and a three-dimensional (3D) metal structure protruding from a top surface of the metal plate. A second dielectric layer surrounds the 3D metal structure. A capacitor dielectric layer covers the 3D metal structure and the second dielectric layer. A top electrode is disposed on the capacitor dielectric layer. The top electrode has fins that interdigitate with the 3D metal structure.

These and other objectives of the present invention will no doubt become obvious to those of ordinary skill in the art after reading the following detailed description of the preferred embodiment that is illustrated in the various drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 to FIG. 9 are schematic, cross-sectional diagrams showing an exemplary method for fabricating a metal-insulator-metal (MIM) capacitor according to one embodiment of the invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present disclosure.

The following detailed description is, therefore, not to be taken in a limiting sense, and the scope of the present invention is defined only by the appended claims, along with the full scope of equivalents to which such claims are entitled.

The term “substrate” used herein includes any structure having an exposed surface onto which a layer is deposited according to the present invention, for example, to form the integrated circuit (IC) structure. The term “substrate” is understood to include semiconductor wafers. The term “substrate” is also used to refer to semiconductor structures during processing, and may include other layers that have been fabricated thereupon.

FIGS. 1 through 9 are schematic, cross-sectional diagrams showing an exemplary method for fabricating a metal-insulator-metal (MIM) capacitor according to one embodiment of the invention.

As shown in FIG. 1, a substrate 100 is provided. The substrate 100 may comprise a bulk semiconductor substrate, such as a bulk silicon substrate. It is understood that the substrate 100 may comprise doped and undoped semiconductors, epitaxial semiconductor layers supported by a base semiconductor or insulator, as well as other semiconductor structures well known to one skilled in the art.

According to one embodiment, the substrate 100 may comprise a main surface 100a. On or in the main surface 100a, for example, a plurality of semiconductor elements such as MOS transistors (not shown) may be fabricated. According to one embodiment, at least one dielectric layer 110 such as an inter-metal dielectric (IMD) layer is deposited on the main surface 100a. For example, the dielectric layer 110 may comprise silicon oxide, silicon nitride, silicon oxy-nitride, borophosphosilicate glass (BPSG), phosphosilicate glass (PSG), but is not limited thereto.

According to one embodiment, at least one damascened metal plate 112 is formed in the dielectric layer 110 within a capacitor forming region CR. Optionally, a damascened metal wire 114 may be formed in the dielectric layer 110 outside the capacitor forming region CR. According to one embodiment, the damascened metal plate 112 and the damascened metal wire 114 may be formed by using copper damascene processes known in the art. According to one embodiment, the damascened metal plate 112 and the damascened metal wire 114 may be formed in a first metal layer or M1.

For example, the damascened metal plate 112 may comprise a copper layer 120a and a diffusion barrier 122a surrounding the copper layer 120a. The diffusion barrier 122a, such as Ti/TiN, Ta/TaN or the like, may prevent copper from diffusing into the dielectric layer 110. Likewise, the damascened metal wire 114 may comprise a copper layer 120b and a diffusion barrier 122b surrounding the copper layer 120b.

Typically, during the copper damascene process, a chemical-mechanical polishing (CMP) may be performed to remove the excess copper from top surface 110a of the dielectric layer 110. Therefore, at this point, top surface 112a of the damascened metal plate 112 and top surface 114a of the damascened metal wire 114 may be flush with the top surface 110a of the dielectric layer 110.

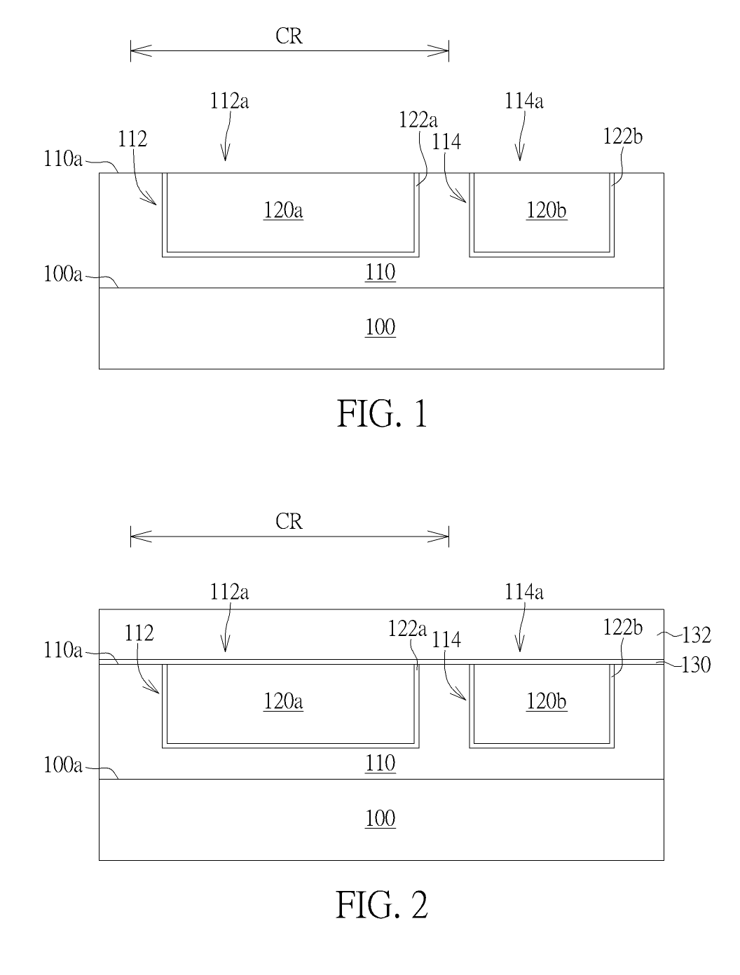

As shown in FIG. 2, a seed layer 130 such as a copper seed layer is deposited onto the top surface 112a of the damascened metal plate 112, the top surface 114a of the damascened metal wire 114, and the top surface 110a of the dielectric layer 110. Subsequently, a photoresist layer 132 may be formed on the seed layer 130.

As shown in FIG. 3, a lithographic process including, but not limited to, an exposure process and a development process, may be performed to form openings 132a in the photoresist layer 132. The patterns of the openings 132a may include, but are not limited to, via trenches, line-shaped trenches, wave-shaped trenches, concentric trenches, or irregular-shaped trenches. The openings 132a are formed directly above the damascened metal plate 112 and are formed only within the capacitor forming region CR.

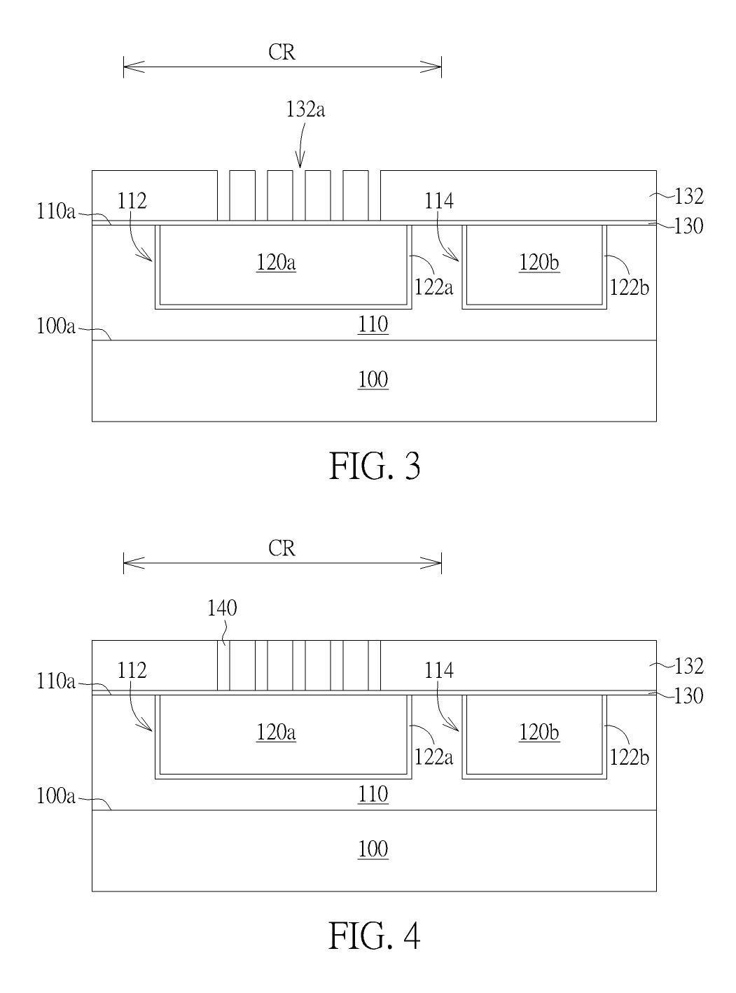

As shown in FIG. 4, a plating process such as a self-alignment plating (SAP) is then carried out to form a three-dimensional (3D) metal structure 140 in the openings 132a. According to one embodiment, the 3D metal structure 140 comprises copper, but is not limited thereto. According to one embodiment, the 3D metal structure 140 has a crown-shaped sectional profile, but is not limited thereto. According to one embodiment, the 3D metal structure 140 is not formed onto the top surface of the photoresist layer 132. By controlling the parameters of the plating process, the height of the 3D metal structure 140 above the top surface 112a of the damascened metal plate 112 may be approximately 70% to approximately 100% of the depth of the openings 132a.

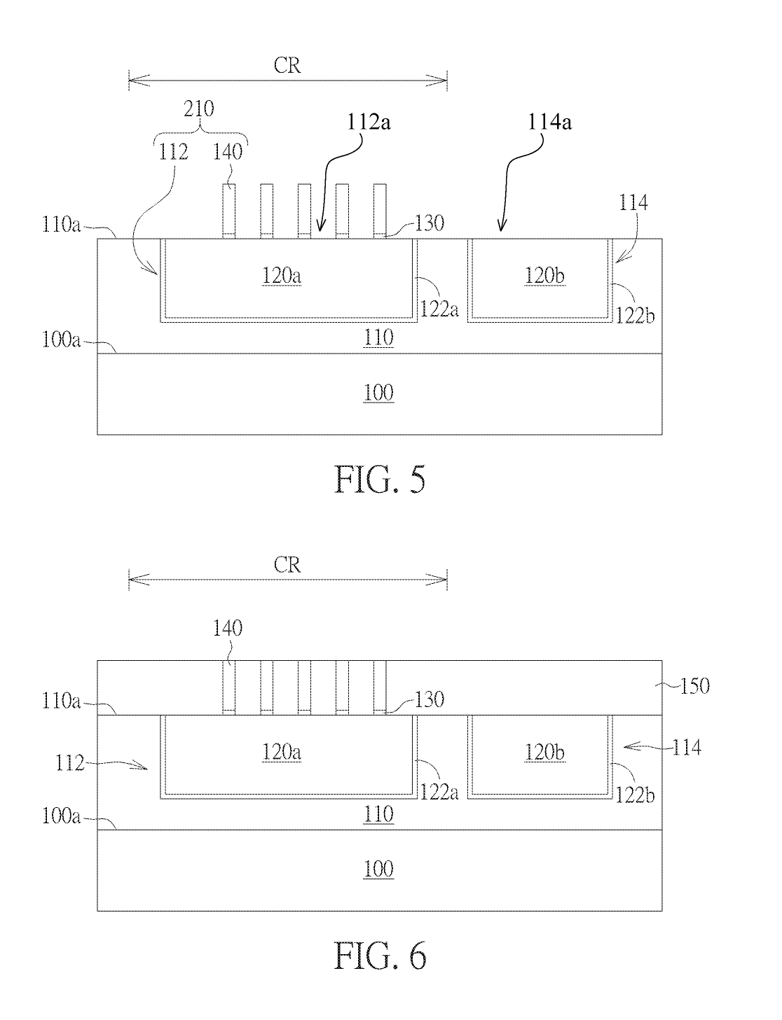

As shown in FIG. 5, after the formation of the 3D metal structure 140, the photoresist layer 132 is removed to reveal the sidewalls of the 3D metal structure 140. According to the pattern of the openings 132a defined in the photoresist layer 132, the 3D metal structure 140 may be a via-shaped, a line-shaped, a wave-shaped, a concentric, or an irregular-shaped structure. After removing the photoresist layer 132, the seed layer 130 not covered by the 3D metal structure 140 is etched away, thereby exposing the top surface 112a of the damascened metal plate 112, the top surface 114a of the damascened metal wire 114, and the top surface 110a of the dielectric layer 110.

At this point, the 3D metal structure 140 protrudes from the top surface 112a of the damascened metal plate 112. According to one embodiment, the 3D metal structure 140 and the damascened metal plate 112 together constitute a bottom electrode 210 of a MIM capacitor.

As shown in FIG. 6, a dielectric layer 150 is deposited over substrate 100 and covers the 3D metal structure 140, the top surface 112a of the damascened metal plate 112, the top surface 114a of the damascened metal wire 114, and the top surface 110a of the dielectric layer 110. The dielectric layer 150 may comprise an inter-layer dielectric (IMD) layer such as silicon oxide, silicon nitride, silicon oxy-nitride, BPSG, PSG, low-k dielectric, or the like. A CMP process may be performed to planarize the dielectric layer 150 until the top surface of the 3D metal structure 140 is exposed.

As shown in FIG. 7, a photoresist layer 160 is formed on the dielectric layer 150. The photoresist layer 160 comprises an opening 160a within the capacitor forming region CR. The opening 160a exposes the top surface of the 3D metal structure 140 and a portion of the dielectric layer 150. Subsequently, an etching process such as a dry etching process is performed to selectively remove the exposed portion of the dielectric layer 150 through the opening 160a, thereby forming recesses 162 between the sidewalls of the 3D metal structure 140. The photoresist layer 160 is then removed. The remaining dielectric layer 150 covers the peripheral region on the top surface 112a of the damascened metal plate 112.

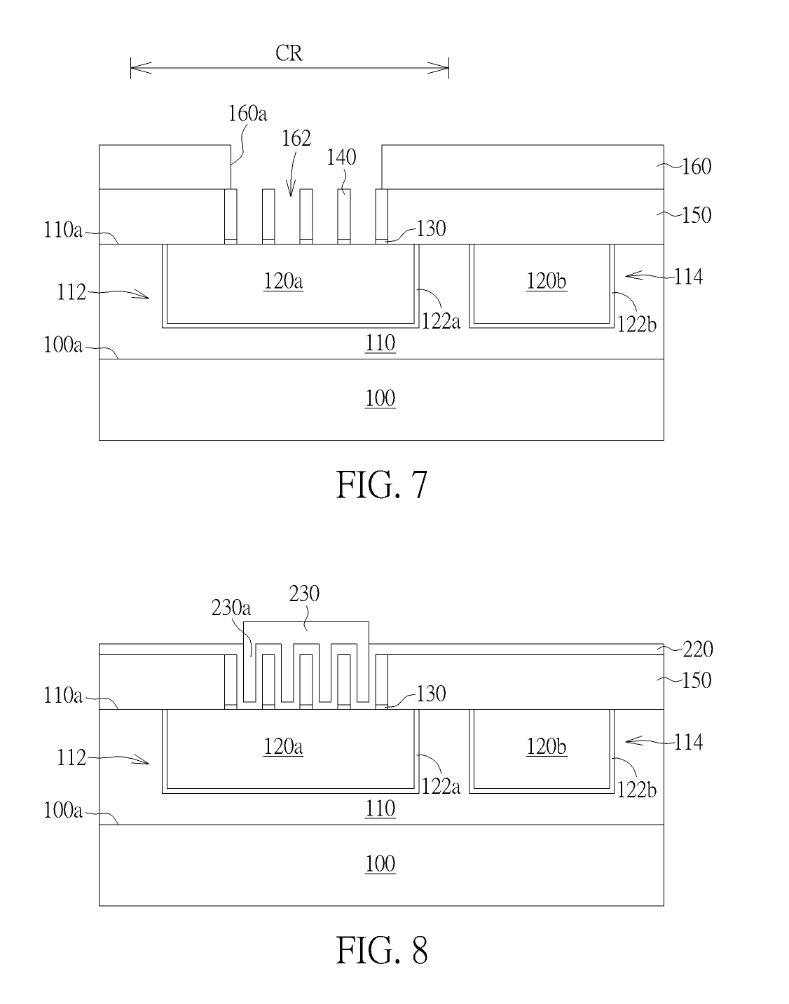

As shown in FIG. 8, a capacitor dielectric layer 220 is conformally deposited on the 3D metal structure 140 and in the recesses 162. The capacitor dielectric layer 220 is also deposited onto the dielectric layer 150. According to one embodiment, the capacitor dielectric layer 220 may be deposited by using chemical vapor deposition (CVD) methods, atomic layer deposition (ALD) methods, or any suitable methods known in the art. According to one embodiment, the capacitor dielectric layer 220 does not completely fill up the recesses 162.

In one embodiment, the capacitor dielectric layer 220 may be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y2OₓN_{y}, SiON, SiNₓ, a silicate thereof, and an alloy thereof.

Subsequently, a top electrode 230 is formed on the capacitor dielectric layer 220 within the capacitor forming region CR. The top electrode 230 completely fills up the recesses 162, thereby forming fins 230a that interdigitate with the 3D metal structure 140. The top electrode 230 is capacitively coupled to the bottom electrode 210 through the capacitor dielectric layer 220.

The top electrode 230 may be formed by using a method that is similar to the process used to form the 3D metal structure 140 as previously mentioned. For example, a seed layer (not shown) may be deposited in a blanket manner, and then a photoresist layer is formed on the seed layer, followed by a self-alignment plating process. After removing the photoresist layer, the excess seed layer is removed.

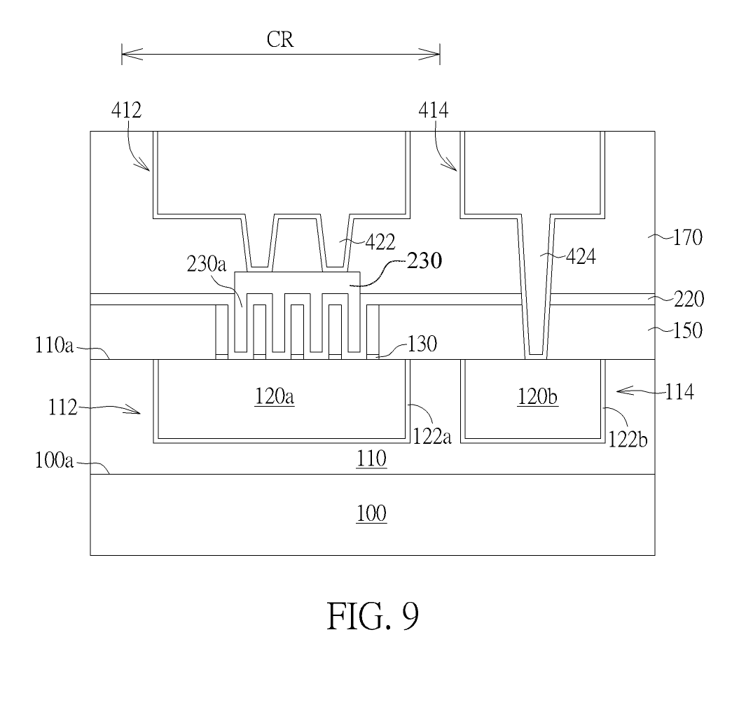

As shown in FIG. 9, a dielectric layer 170 is deposited on the capacitor dielectric layer 220 in a blanket manner. The dielectric layer 170 covers the top electrode 230 and the capacitor dielectric layer 220. Subsequently, damascened metal interconnect structures 412 and 414 are formed in the dielectric layer 170 by using a copper dual damascene process. The damascened metal interconnect structure 412 may be formed within the capacitor forming region CR, and may include a via 422 that is electrically coupled to the top electrode 230. The damascened metal interconnect structure 414 may include a via 424 that is electrically coupled to the damascened metal wire 114. The via 424 penetrates through the capacitor dielectric layer 220 and partially through the dielectric layer 150.

Those skilled in the art will readily observe that numerous modifications and alterations of the device and method may be made while retaining the teachings of the invention. Accordingly, the above disclosure should be construed as limited only by the metes and bounds of the appended claims.

1. A metal-insulator-metal (MIM) capacitor, comprising:
a substrate having a first dielectric layer thereon;
a bottom electrode comprising a metal plate in the first dielectric layer and a three-dimensional
(3D) metal structure protruding from a top surface of the metal plate; a second dielectric layer surrounding the 3D metal structure;
a capacitor dielectric layer in direct contact with 3D metal structure and in direct contact with the second dielectric layer; and
a top electrode comprising fins on the capacitor dielectric layer, each fin interdigitating with the 3D metal structure and each fin in direct contact with the capacitor dielectric layer.

2. The MIM capacitor according to claim 1, wherein the metal plate is a damascened metal plate.

3. The MIM capacitor according to claim 1, wherein the second dielectric layer covers a peripheral region on the top surface of the metal plate.

4. The MIM capacitor according to claim 1, further comprising a third dielectric layer covering the top electrode and the capacitor dielectric layer.

5. The MIM capacitor according to claim 4, further comprising a damascened metal interconnect structure embedded in the third dielectric layer and electrically connected to the top electrode.

6. The MIM capacitor according to claim 1, wherein the 3D metal structure comprises a via-shaped structure, a line-shaped structure, a wave-shaped structure, a concentric structure, or an irregular-shaped structure.

7. The MIM capacitor according to claim 1, wherein the metal plate comprises copper.

8. The MIM capacitor according to claim 1, wherein the 3D metal structure comprises copper.

9. The MIM capacitor according to claim 1, wherein the top electrode comprises copper.

10. The MIM capacitor according to claim 1, further comprising a seed layer between the 3D metal structure and the metal plate.

11. A metal-insulator-metal (MIM) capacitor, comprising:
a metal plate in a first dielectric material and a three-dimensional (3D) metal structure above the metal plate;
a second dielectric material laterally adjacent the 3D metal structure;
a capacitor dielectric material in direct contact with the 3D metal structure and with the second dielectric material; and
fins in direct contact with the capacitor dielectric material and each fin interdigitating with the 3D metal structure, an upper surface of the fins extending above an upper surface of the capacitor dielectric material.

12. The MIM capacitor according to claim 11, wherein the 3D metal structure comprises a crown-shaped sectional profile.

13. The MIM capacitor according to claim 11, further comprising a seed material between the metal plate and the 3D metal structure.

14. The MIM capacitor according to claim 11, wherein the metal plate and the 3D metal structure comprise a bottom electrode.

15. The MIM capacitor according to claim 11, wherein the fins comprise a top electrode.

16. The MIM capacitor according to claim 11, wherein the capacitor dielectric material comprises a high-k dielectric material.

17. The MIM capacitor according to claim 11, wherein the capacitor dielectric material is in direct contact with sidewalls of the 3D metal structure and with horizontal surfaces of the metal plate and the 3D metal structure.

18. A metal-insulator-metal (MIM) capacitor, comprising:
a bottom electrode comprising a metal plate and a three-dimensional (3D) metal structure above the metal plate;
a dielectric material laterally adjacent the 3D metal structure and over the metal plate;
a capacitor dielectric material in direct contact with the 3D metal structure and in direct contact with an upper surface of the dielectric material laterally adjacent the 3D metal structure; and
fins of a top electrode in direct contact with the capacitor dielectric material and each fin interdigitating with the 3D metal structure.

19. The MIM capacitor according to claim 18, wherein the bottom electrode, the capacitor dielectric material, and the top electrode are in a capacitor forming region.

20. The MIM capacitor according to claim 19, further comprising a metal wire outside the capacitor forming region.
